(19) United States
(12) Patent Application Publication
(10) Pub. No.: US 2026/0126911 A1
(43) Pub. Date: May 7, 2026

(54) METHODS AND APPARATUSES FOR OPERATING A MEMORY DEVICE

(71) Applicant: Yangtze Memory Technologies Co., Ltd., Wuhan (CN)

(72) Inventors: Xingwei TANG, Wuhan (CN); Lu GUO, Wuhan (CN); Zhuqin DUAN, Wuhan (CN); Wen LUO, Wuhan (CN); Kun REN, Wuhan (CN)

(21) Appl. No.: 19/019,931

(22) Filed: Jan. 14, 2025

Related U.S. Application Data
(63) Continuation of application No. PCT/CN2024/129641, filed on Nov. 4, 2024.

(51) Int. Cl. G06F 3/06

(52) U.S. Cl. CPC G06F 3/061; G06F 3/0653; G06F 3/0659; G06F 3/0679

(57) ABSTRACT

Example memory devices, memory systems, and methods for identifying zero pages in a memory device are disclosed. In one example, a method of operating a memory device includes performing, based on a first read voltage, a read operation on memory cells coupled to a word line of the memory device; determining a quantity of failed memory cells, the failed memory cells being memory cells having threshold voltages lower than the first read voltage; and in response to determining that the quantity of the failed memory cells is less than a threshold, ending the read operation.

### CROSS-REFERENCE TO RELATED APPLICATIONS

This application is a continuation of International Application No. PCT/CN2024/129641, filed on Nov. 4, 2024, the disclosure of which is hereby incorporated by reference in its entirety.

### TECHNICAL FIELD

This present disclosure generally relates to the field of semiconductor technology, and more particularly, to systems and methods for performing read operations in a memory device.

### BACKGROUND

Flash memory is a low-cost, high-density, nonvolatile solid-state storage medium that can be electrically erased and reprogrammed. Flash memory includes NOR flash memory and NAND flash memory. Various operations can be performed by flash memory, for example, program (write) and erase operations, to change the threshold voltage of each memory cell to a respective level. For NAND flash memory, an erase operation can be performed at the block level, a program operation can be performed at the page level, and a read operation can be performed at the page level.

### SUMMARY

The present disclosure involves methods, apparatuses, and systems for performing read operations in a memory device. One aspect of the present disclosure features an example method for operating a memory device. The method includes performing, based on a first read voltage, a read operation on memory cells coupled to a word line of the memory device; determining a quantity of failed memory cells, the failed memory cells being memory cells having threshold voltages lower than the first read voltage; and in response to determining that the quantity of the failed memory cells is less than a threshold, ending the read operation.

In some implementations, the threshold is a value that is less than 5% of a quantity of memory cells coupled to the word line.

In some implementations, determining the quantity of the failed memory cells includes determining, in latches of a page buffer of the memory device, a quantity of memory cells that are read as “1”.

In some implementations, the method includes, in response to determining that the quantity of the failed memory cells is less than the threshold, sending a response indicating that a memory page associated with the word line is a zero page.

In some implementations, the zero page is associated with a word line coupled to a set of memory cells. Threshold voltages of the set of memory cells are higher than a threshold level that is higher than a starting read voltage for reading each of a plurality of memory pages of the memory device.

In some implementations, the memory cells are triple-level cells. The first read voltage is a starting read voltage for reading one of a lower page, a middle page, or an upper page associated with the word line.

In some implementations, the memory cells are quad-level cells. The first read voltage is a starting read voltage for reading one of a lower page, a middle page, an upper page, or an extra page associated with the word line.

In some implementations, the method includes performing the read operation in response to receiving a specific command indicating to identify zero pages in the memory device.

In some implementations, the method includes performing the read operation in response to receiving a read command and determining that an enable bit stored in the memory device indicates the memory device to identify zero pages when performing the read operation.

In some implementations, the method includes, in response to determining that the quantity of failed memory cells is greater than or equal to the threshold, performing the read operation based on a second read voltage on the memory cells. The second read voltage is higher than the first read voltage.

Another aspect of the present disclosure features a memory device. The memory device includes a memory array including memory cells coupled to a word line, and a peripheral circuit coupled to the memory array. The peripheral circuit is configured to perform operations including performing, based on a first read voltage, a read operation on memory cells coupled to a word line of the memory device; determining a quantity of failed memory cells, the failed memory cells being memory cells having threshold voltages lower than the first read voltage; and in response to determining that the quantity of the failed memory cells is less than a threshold, ending the read operation.

In some implementations, the threshold is a value that is less than 5% of a quantity of memory cells coupled to the word line.

In some implementations, determining the quantity of the failed memory cells includes determining, in latches of a page buffer of the memory device, a quantity of memory cells that are read as “1”.

In some implementations, the operations include in response to determining that the quantity of the failed memory cells is less than the threshold, sending a response indicating that a memory page associated with the word line is a zero page.

In some implementations, the zero page is associated with a word line coupled to a set of memory cells. Threshold voltages of the set of memory cells are higher than a threshold level that is higher than a starting read voltage for reading each of a plurality of memory pages of the memory device.

In some implementations, the memory cells are triple-level cells. The first read voltage is a starting read voltage for reading one of a lower page, a middle page, or an upper page associated with the word line.

In some implementations, the memory cells are quad-level cells. The first read voltage is a starting read voltage for reading one of a lower page, a middle page, an upper page, or an extra page associated with the word line.

Another aspect of the present disclosure features a memory system. The memory system includes a memory device and a memory controller coupled to the memory device. The memory device is configured to perform operations including receiving a read command from the memory controller; performing, based on a first read voltage, a read operation on the memory cells; and in response to a result of the read operation, sending a response to the memory controller. The response indicates that a memory page associated with the word line is a zero page.

In some implementations, the operations include determining a quantity of failed memory cells. The failed memory cells are memory cells having threshold voltages lower than the first read voltage. The memory device is configured to send the response to the memory controller in response to determining that the quantity of the failed memory cells is less than a threshold.

In some implementations, the operations include, in response to determining that the quantity of the failed memory cells is less than the threshold, ending the read operation.

While generally described as computer-implemented software embodied on tangible media that processes and transforms the respective data, some or all of the aspects may be computer-implemented methods or further included in respective systems or other devices for performing this described functionality. The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates an example of a schematic diagram of a memory device including peripheral circuits, according to some aspects of the present disclosure.

FIG. 2 illustrates an example of a side view of cross-sections of a memory cell array including NAND memory strings, according to some aspects of the present disclosure.

FIG. 3 illustrates some example peripheral circuits, according to some aspects of the present disclosure.

FIG. 4 illustrates a schematic diagram of an example page buffer of a memory device, according to some aspects of the present disclosure.

FIG. 5A illustrates an example of threshold voltage distributions of memory cells in a triple-level cell (TLC) memory device, according to some aspects of the present disclosure.

FIG. 5B illustrates a schematic diagram of an example threshold voltage distribution of memory cells associated with a zero page in a TLC memory device, according to some aspects of the present disclosure.

FIG. 5C illustrates a schematic diagram of an example threshold voltage distribution of memory cells associated with a zero page in a TLC memory device, according to some aspects of the present disclosure.

FIG. 6 illustrates an example of voltages applied to a word line during a read operation to read data from a memory page, according to some aspects of the present disclosure.

FIG. 7 illustrates an example of voltages applied to a word line during a read operation to identify a zero page, according to some aspects of the present disclosure.

FIG. 8A illustrates an example of threshold voltage distributions of memory cells in a quad-level cell (QLC) memory device, according to some aspects of the present disclosure.

FIG. 8B illustrates a schematic diagram of an example threshold voltage distribution of memory cells associated with a zero page in a QLC memory device, according to some aspects of the present disclosure.

FIG. 9 illustrates a flow chart of an example process of performing a read operation, according to some aspects of the present disclosure.

FIG. 10 illustrates a flow chart of another example process performing a read operation, according to some aspects of the present disclosure.

FIG. 11 illustrates a block diagram of an example system having a memory device, according to some aspects of the present disclosure.

FIG. 12A illustrates a diagram of a memory card having a memory device, according to some aspects of the present disclosure.

FIG. 12B illustrates a diagram of a solid-state drive (SSD) having a memory device, according to some aspects of the present disclosure.

Like reference numbers and designations in the various drawings indicate like elements.

### DETAILED DESCRIPTION

A memory device, such as a NAND memory device, can store data in memory pages. In some cases, a memory page can be programmed into a zero page (e.g., comprising all zeros) that does not include valid data. For example, the memory device can program memory pages into zero pages to quickly close an open word line, or close an open block.

To program a zero page, memory cells associated with the zero page are programmed to a state higher than a threshold level. The threshold level is higher than a starting read voltage for reading each memory page of the memory device. For example, in a triple-level cell (TLC) memory device, the threshold level is higher than starting read voltages for reading a lower page, a middle page, and an upper page, respectively. For example, in a quad-level cell (QLC) memory device, the threshold level is higher than starting read voltages for reading a lower page, a middle page, an upper page, and an extra page, respectively.

In some cases, a memory system that includes a memory device and a memory controller identifies a zero page by performing a read operation on a memory page. By applying a set of read voltages, the memory device can read data from the memory page, and send the data to the memory controller. The memory controller can determine whether the data comprises all zeros, and thereby determine whether the memory page is a zero page.

The present disclosure provides techniques to identify zero pages in a faster and more efficient way. In some implementations, the memory device can apply a starting read voltage (e.g., VR1) to read a memory page (e.g., a lower page of a TLC memory device), and determine a quantity of failed memory cells among the memory cells associated with the memory page. The threshold voltages of the failed memory cells are lower than the starting read voltage. If the quantity of failed memory cells is less than a threshold value (e.g., 10% or 5% of the quantity of memory cells associated with the memory page), the memory device can identify the memory page as a zero page. In such case, the memory device can end the read operation without applying subsequent read voltages, and send a response to the memory controller indicating that the memory page being read is a zero page. As such, the memory device can identify zero pages without sending data to the memory controller.

The described techniques can achieve one or more technical effects. For example, the described techniques can reduce the read time to identify a zero page, as compared to the scenario where the memory device applies a set of read voltages to read data from the zero page. For another example, the described techniques can identify a zero page without sending data to the memory controller, which can reduce the usage of buffer space in the memory controller. In addition, the memory device can determine the quantity of failed memory cells by using existing circuits of a page buffer of the memory device, without needing to design additional circuits, which is a cost-effective way to increase the efficiency of identifying zero pages. In some implementations, additional or different technical effects can be achieved.

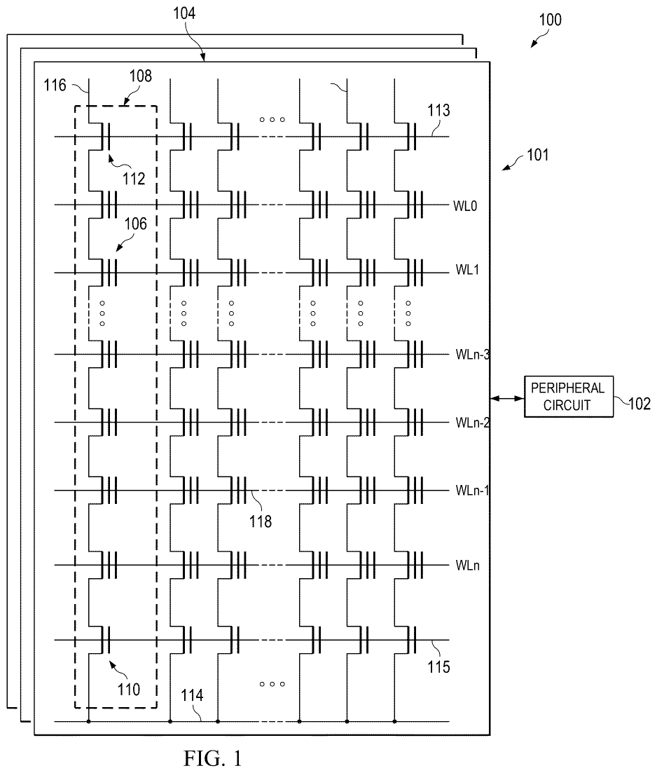

FIG. 1 illustrates an example of a schematic circuit diagram of a memory device 100 including peripheral circuits, according to some aspects of the present disclosure. The memory device 100 can include a memory cell array 101 and peripheral circuits 102 coupled to the memory cell array 101. The memory cell array 101 can be a NAND Flash memory cell array in which memory cells 106 are provided in the form of an array of NAND memory strings 108 each extending vertically above a substrate (not shown in FIG. 1). In some implementations, each NAND memory string 108 includes a plurality of memory cells 106 coupled in series and stacked vertically. Each memory cell 106 can hold a continuous, analog value, such as an electrical voltage or charge that depends on the number of electrons trapped within a storage layer of the memory cell 106. The logic state (i.e., data) of each memory cell 106 in the block 104 can be determined based on the threshold voltage of the memory cell 106. Each memory cell 106 can be a floating gate type memory cell including a floating-gate transistor, or a charge trap type memory cell including a charge-trap transistor.

In some implementations, each memory cell 106 is a single-level cell (SLC) with two possible memory states that can store one bit of data. For example, the first memory state “0” can correspond to a first range of voltages, and the second memory state “1” can correspond to a second range of voltages. In some implementations, each memory cell 106 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state.

As shown in FIG. 1, each NAND memory string 108 can include a source select gate (SSG) 110 at its source end and a drain select gate (DSG) 112 at its drain end. The SSG 110 and the DSG 112 can be configured to activate selected NAND memory strings 108 (columns of the array) during read and program operations. In some implementations, the sources of NAND memory strings 108 in the same block 104 are coupled through a same source line (SL) 114, e.g., a common SL. In other words, NAND memory strings 108 in the same block 104 have an array common source (ACS), according to some implementations. The DSG 112 of each NAND memory string 108 is coupled to a respective bit line 116 from which data can be read or written via an output bus (not shown), according to some implementations. In some implementations, each NAND memory string 108 is configured to be selected or deselected by applying a select voltage (e.g., above the threshold voltage of the transistor having the DSG 112) or a deselect voltage (e.g., 0 V) to the respective DSG 112 through one or more DSG lines 113, and/or by applying a select voltage (e.g., above the threshold voltage of the transistor having the SSG 110) or a deselect voltage (e.g., 0 V) to the respective SSG 110 through one or more SSG lines 115.

As shown in FIG. 1, NAND memory strings 108 can be organized into multiple blocks 104, each of which can have a common source line 114 coupled to the ACS. In some implementations, each block 104 can serve as a basic data unit for erase operations, such that memory cells 106 on the same block 104 are erased at the same time. To erase memory cells 106 in a selected block 104, the source lines 114 coupled to the selected block 104 and unselected blocks in the same plane can be biased with an erase voltage. For example, the erase voltage can be a high positive voltage (e.g., 20 V or more). In some implementations, an erase operation can be performed at a half-block level, a quarter-block level, or a level having any suitable number of blocks or fractions of a block.

The memory cells 106 of adjacent NAND memory strings 108 can be coupled through word lines 118. The word line 118 can select which row of memory cells 106 is affected by read and program operations. In some implementations, the memory cell 106 is a SLC, and each word line 118 correspond to one memory page. A memory page is the basic data unit for program operations. If the memory cell 106 is an MLC that stores two bits of data per cell, each word line 118 can correspond to two memory pages. If memory cell 106 is a TLC, each word line 118 can correspond to three memory pages, including a lower page, a middle page, and an upper page. If memory cell 106 is a QLC, each word line 118 can correspond to four memory pages, including a lower page, a middle page, an upper page, and an extra page. The memory page refers to a logic page in the present disclosure. The size of a memory page in bits is associated with the number of NAND memory strings 108 coupled by word line 118 in a block 104. Each word line 118 can include a gate line coupled to a plurality of control gates (gate electrodes) of a plurality of memory cells 106 in the respective memory page. Example word lines shown in FIG. 1 include WL0, WL1, . . . , WLn-3, WLn-2, WLn-1, and WLn that are between one or more DSG lines 113 and one or more SSG lines 115.

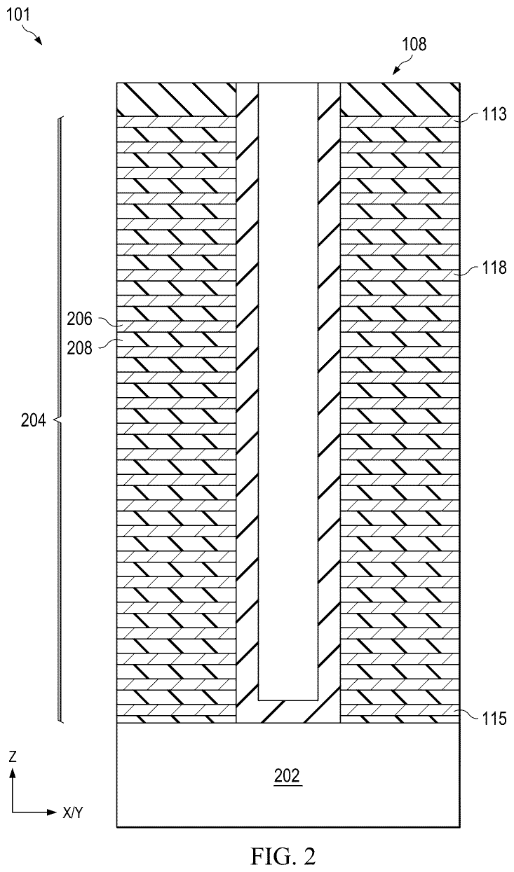

FIG. 2 illustrates an example of a side view of cross-sections of a memory cell array 101 including NAND memory strings 108, according to some aspects of the present disclosure. As shown in FIG. 2, the NAND memory string 108 can extend vertically through a memory stack 204 above a substrate 202. The substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

The memory stack 204 can include pairs of interleaved gate conductive layers 206 and gate-to-gate dielectric layers 208. The quantity of the pairs of the interleaved gate conductive layers 206 and gate-to-gate dielectric layers 208 in a memory stack 204 can determine the quantity of memory cells 106 in memory cell array 101. The gate conductive layer 206 can include conductive materials including, but not limited to, one or more of tungsten (W), cobalt (Co), copper (Cu), aluminum (Al), polysilicon, doped silicon, or silicide. In some implementations, each gate conductive layer 206 includes a metal layer, such as a tungsten layer. In some implementations, each gate conductive layer 206 includes a doped polysilicon layer. Each gate conductive layer 206 can include control gates surrounding the memory cells 106, the DSG 112, or the SSG 110, and can extend laterally as the DSG line 113 at the top of memory stack 204, the SSG line 115 at the bottom of memory stack 204, or the word lines 118 between the DSG line 113 and the SSG line 115.

Peripheral circuits 102 can be coupled to the memory cell array 101 through bit lines 116, word lines 118, source lines 114, SSG lines 115, and DSG lines 113. The peripheral circuits 102 can include any suitable analog, digital, and mixed-signal circuits for facilitating the operations of the memory cell array 101 by applying and sensing voltage signals and/or current signals to and from each target memory cell 106 through bit lines 116, word lines 118, source lines 114, SSG lines 115, and DSG lines 113. The peripheral circuits 102 can include various types of peripheral circuits formed using metal-oxide-semiconductor (MOS) technologies.

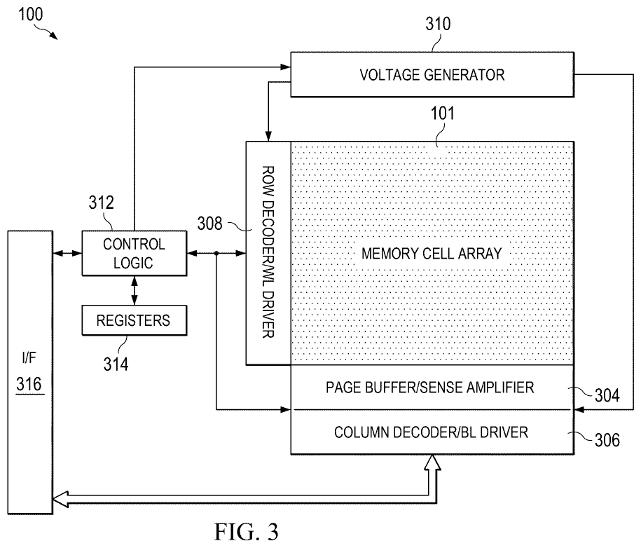

FIG. 3 illustrates some example peripheral circuits, according to some aspects of the present disclosure. The example peripheral circuits include a page buffer/sense amplifier 304, a column decoder/bit line driver 306, a row decoder/word line driver 308, a voltage generator 310, control logic 312, registers 314, an interface 316, and a data bus. In some examples, additional peripheral circuits not shown in FIG. 3 may be included as well.

The page buffer/sense amplifier 304 can be configured to read and program (write) data from and to memory cell array 101 according to the control signals from control logic 312. In an example, the page buffer/sense amplifier 304 may store one page of program data (write data) to be programmed into one memory page of the memory cell array 101. In another example, the page buffer/sense amplifier 304 may perform program verify operations to ensure that the data has been properly programmed into memory cells 106 coupled to selected word lines 118. In still another example, the page buffer/sense amplifier 304 may also sense the low power signals from the bit line 116 that represents a data bit stored in memory cell 106, and amplify the small voltage swing to recognizable logic levels in a read operation. The column decoder/bit line driver 306 can be configured to be controlled by the control logic 312 and select one or more NAND memory strings 108 by applying bit line voltages generated from the voltage generator 310.

The row decoder/word line driver 308 can be configured to be controlled by the control logic 312 and select/deselect blocks 104 of the memory cell array 101 and select/deselect word lines 118 of the block 104. The row decoder/word line driver 308 can be further configured to drive word lines 118 using word line voltages generated from the voltage generator 310. In some implementations, the row decoder/word line driver 308 can also select/deselect and drive SSG lines 115 and DSG lines 113. As described below in detail, the row decoder/word line driver 308 is configured to apply a program voltage to selected word line 118 in a program operation on memory cell 106 coupled to selected word line 118.

The voltage generator 310 can be configured to be controlled by the control logic 312 and generate the word line voltages (e.g., read voltage, program voltage, pass voltage, local voltage, verify voltage, etc.), bit line voltages, and source line voltages to be supplied to the memory cell array 101.

The control logic 312 can be coupled to each peripheral circuit described above and configured to control operations of each peripheral circuit. The registers 314 can be coupled to the control logic 312 and include status registers, command registers, and address registers for storing status information, command operation codes (OP codes), and command addresses for controlling the operations of each peripheral circuit.

The interface 316 can be coupled to the control logic 312 and act as a control buffer to buffer and relay control commands received from a host (not shown) to the control logic 312 and status information received from the control logic 312 to the host. The interface 316 can also be coupled to the column decoder/bit line driver 306 via a data bus, and act as a data input/output (I/O) interface and a data buffer to buffer and relay data to and from the memory cell array 101.

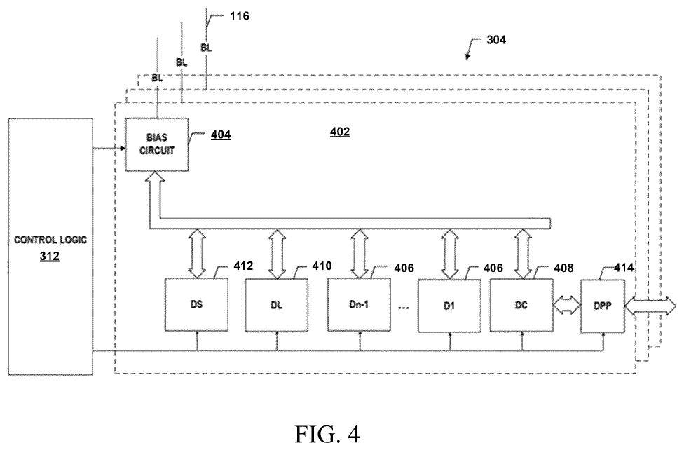

FIG. 4 illustrates a schematic diagram of an example page buffer (e.g., page buffer/sense amplifier 304 of FIG. 3) of a memory device, according to some aspects of the present disclosure. The page buffer/sense amplifier 304 can include a plurality of page buffer circuits 402 each coupled to a respective one of the bit lines 116. In other words, each page buffer circuit 402 can be coupled to a memory string 108 through a corresponding bit line 116 and configured to temporarily store data to be written into memory cells 106 during a program operation, and can temporarily store sensing results during a program verification operation or a read operation.

In some implementations, the page buffer circuit 402 can include a bias circuit 404, a set of data latches 406 (D1, . . . , Dn-1), a data cache (DC) latch 408, a 3BL/4BL (DL) latch 410, and a data sense (DS) latch 412, and a data pre-processing (DPP) circuit 414.

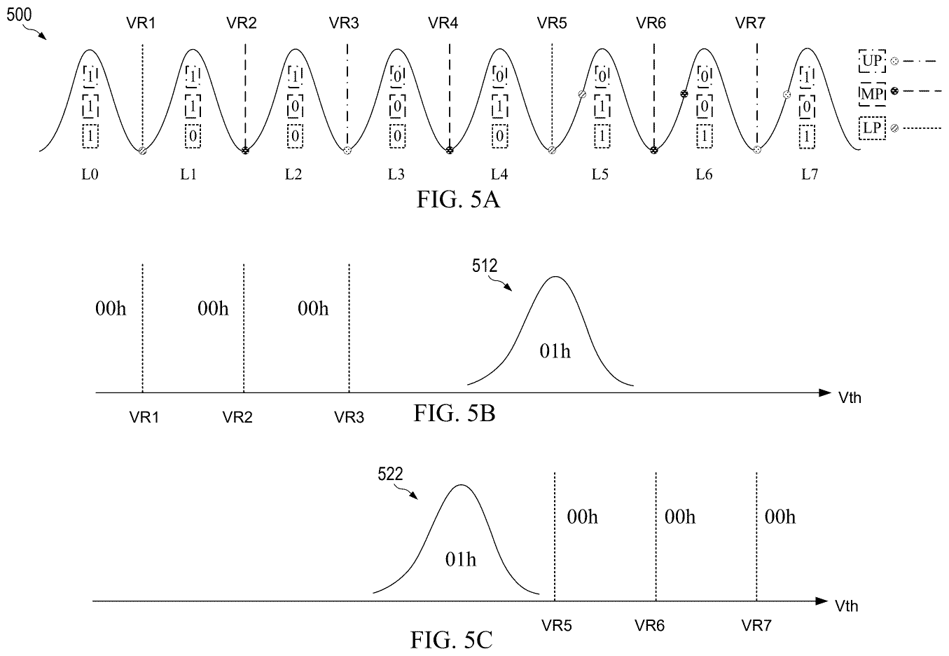

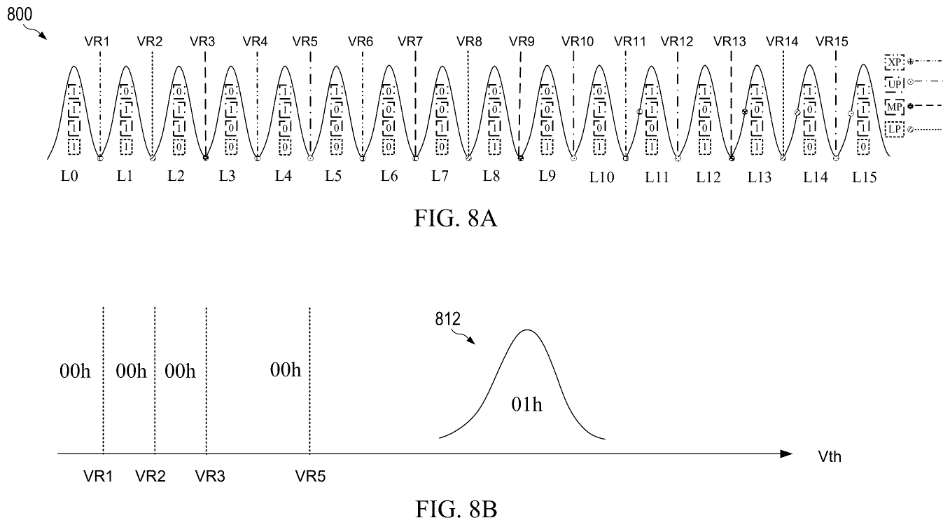

The DPP circuit 414 is configured to receive a respective portion of the raw data (e.g., N bits of raw data page) from a data bus, and convert the raw data to the corresponding N bits of the current data page based on a preset Gray code (e.g., the example shown in FIG. 5A and FIG. 8A). In some implementations, the DPP circuit 414 is further configured to update the Gray code during a program operation, for example, after verifying a selected row of memory cells 106 at a certain level. In other words, the DPP circuit 414 can enable the page buffer circuit 402 to achieve dynamic data pro-processing (re-DPP) at the programming stage by updating the preset Gray code and converting the raw data page to the current data page again based on the updated Gray code.

Each page buffer circuit 402 can include a set of data latches 406 and a DC latch 408. During a current program operation to program a selected row of memory cells 106 based on a current data page (e.g., converted from a raw data page by DPP circuit 414), each data latch 406 can be configured to store a respective one bit of the N bits of the current data page, and the DC latch 408 can be configured to sequentially store each of the N bits of a next data page.

The page buffer circuit 402 can include a plurality of latches for storing page information other than data bits to be written into the memory cells. As shown in FIG. 4, the page buffer circuit 402 can include a DS latch 412 configured to store information indicative of whether a memory cell 106 coupled to a respective bit line 116 is inhibited from programming during a program operation. The information can indicate whether the memory cell 106 has passed verification at a particular level (thus being inhibited from programming), or failed to pass the verification at the particular level (thus will continue to be programmed). For example, if a memory cell passes verification, a logic value 0 is latched to the DS latch 412; and if a memory cell fails verification, a logic value 1 is latched to the DS latch 412. The sum of logic value “1” in the DS latch 412 can be the result of verify fail count (VFC) corresponding to the particular level. The result of VFC can indicate a quantity of failed memory cells among memory cells coupled to a selected word line, where the failed memory cells have not been programmed to the particular level.

The DS latch 412 may be configured to store other types of page information during a different operation, e.g., during read operations. For example, if a memory cell is switched on under the particular read voltage, a logic value “1” is latched to the DS latch 412; and if a memory cell is switched off under the particular read voltage, a logic value “0” is latched to the DS latch 412. The sum of logic value “1” can be the result of VFC corresponding to the particular read level during the read operation. The result of VFC can include a quantity of failed memory cells among memory cells coupled to a selected word line, where the failed memory cells have threshold voltages lower than the particular read voltage.

In some implementations, the page buffer circuit 402 also includes a DL latch 410 configured to store bias information of the respective bit line 116 coupled to page buffer circuit 402. The bias information can indicate the voltage level applied to the selected memory cell 106 coupled to a respective bit line 116. For example, the voltage applied to bit line 116 (i.e., bit line voltage) at a particular level may be selected from multiple possible bias voltages (e.g., 3 or 4 bias conditions) as indicated by the bias information stored in DL latch 410. In some implementations, the DL latch 410 can also be used as a data latch or a DS latch.

The page buffer circuit 402 can further include a bias circuit 404 coupled to a respective bit line 116. The bias circuit 404 is configured to apply a bit line voltage to memory cells 106 coupled to a respective bit line 116 in the program operation. In some implementations, to optimize the threshold voltage distributions, for example, enlarging the read margins between adjacent levels, the bias circuit 404 is configured to apply one or more medium voltage levels that are between a pass voltage and an inhibit voltage to bias the bit line voltage. For example, three voltage levels, e.g., high, medium, and low, or four voltage levels, e.g., high, medium high, medium low, and low, can be applied to the respective bit line 116 (referred to as 3BL or 4BL).

It should be noted that each storage unit in the page buffer circuit 402, including each data latch 406, DC latch 408, DL latch 410, and DS latch 412, may be any circuit that has two stable states for storing a single bit of data, such as a latch or a flip-flop.

FIG. 5A illustrates an example of a threshold voltage distribution 500 of memory cells in a triple-level cell (TLC) memory device, according to some aspects of the present disclosure. Each memory cell of the TLC memory device (also referred to as triple-level cell or TLC) can be configured to be set as one of eight states L0-L7, where L0 is the erased state and L1-L7 are programmed states. Each state of the TLC corresponds to a range of threshold voltages Vₜₕ, where the Vₜₕ distribution of each state can be represented by a probability density. As shown in FIG. 5A, from the state L0 to the state L7, Vₜₕ of the memory cells increases. In some implementations, each state of the TLC can be programmed by using an incremental step pulse programming (ISPP) scheme, where the program voltage applied to the selected word line can be incrementally increased by adding a step pulse. For example, the eight states of TLC can be programmed, from the erase state L0 to the programmed state L1 having a lower threshold voltage, and then to programmed state L2, L3, . . . L7 having a higher threshold voltage.

The states of a memory cell can be mapped into data in the form of binary codes. For example, the eight states of a TLC can be represented in the form of a Gray code. A Gray code, also referred to as reflected binary code (RBC) or reflected binary (RB), is an ordering of the binary numeral system such that two successive values differ in only one bit (binary digit). Using Gray codes allows for easier error correction in programming and reading operations, since the codes of any adjacent states differ by only one binary digit.

As shown in FIG. 5A, each state of the TLC is mapped into a 3-bit binary code. As an example, the eight states (states L0-L7) of TLC can correspond to 3-bit binary codes (111), (110), (100), (000), (010), (011), (001) and (101), respectively. The 3 bits of the binary codes can be named as a most significant bit (MSB), a center significant bit (CSB), and a least significant bit (LSB), reading from left to right. For example, the state P5 can be mapped to the binary code (011), where the MSB, CSB and LSB are “0,” “1,” and “1,” respectively. In some implementations, the memory cells coupled to the same word line (e.g., word line 118 of FIG. 1) can be read or programmed simultaneously. Memory cells coupled to the same word line (also referred to as a physical page) can store data in three logic pages, including a lower page (LP), a middle page (MP), and an upper page (UP). The memory device can program data into the memory cells according to the LSB, CSB and MSB of the binary codes.

It should be noted that the mapping relationship between states of a memory cell and the gray codes as shown in FIG. 5A is for illustrative purposes. The states of the memory cell can be mapped to the gray codes in a different order, or can be mapped to a different set of binary codes.

During a read operation, the state of a memory cell can be determined by comparing the threshold voltage (Vₜₕ) of the memory cell with one or more read voltages VR (e.g., VR1, VR2, . . . ). A read voltage VR can be within a read margin between two adjacent states, i.e., between a highest possible Vₜₕ of a lower state and a lowest possible Vₜₕ of a higher state. As shown in FIG. 5A, in the TLC memory device, by applying the read voltages VR1-VR7 to the selected word line, the memory device can determine a range of Vₜₕ of a target memory cell coupled to the selected word line. As an example, to verify if the target memory cell is at state L0, the memory device can apply the read voltage VR1 to the word line. If the target memory cell is at state L0, V of the target memory cell is lower than VR1, the target memory cell is therefore switched on to form a conductive path in the channel. If the target memory cell is at any one of the states L1-L7, Vₜₕ of the target memory cell is higher than VR1, the target memory cell is therefore switched off. By measuring or sensing the current through the target memory cell or sensing a voltage drop at the corresponding bit line, the memory device can determine Vₜₕ or the state of the target memory cell.

In some implementations, the states of the memory cells are read and determined according to the logic pages of the mapping scheme. For example, in a TLC memory device, a first subset of the read voltages, e.g., VR3 and VR7, can be used to determine the MSB of the target memory cell (corresponding to the upper page) where “1” is flipped to “0” or “0” is flipped to “1”. Similarly, a second subset of the read voltages, e.g., VR2, VR4 and VR6, can be used to determine the CSB of the target memory cell (corresponding to the middle page), and a third subset of the read voltages, e.g., VR1 and VR5, can be used to determine the LSB of the target memory cell (corresponding to the lower page). Accordingly, data can be read from the upper page (UP) by applying two read voltages to the selected word line. Data can be read from the middle page (MP) by applying three read voltages to the selected word line. Data can be read from the lower page (LP) by applying two read voltages to the selected word line.

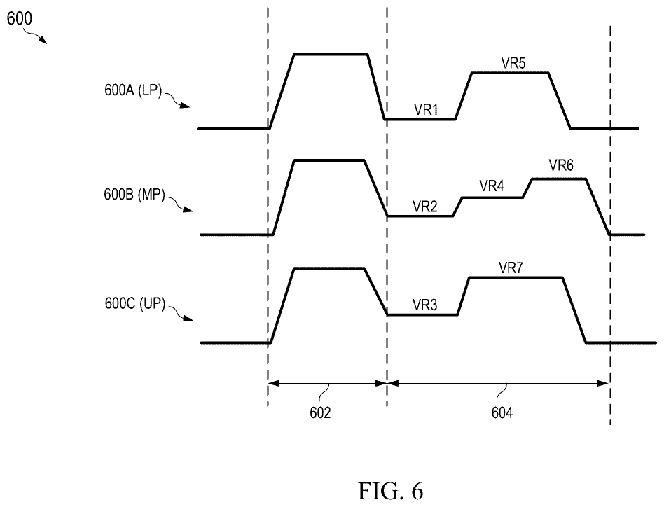

In some implementations, the memory device applies the read voltages in an ascending order, where a lower read voltage is applied before a higher read voltage. For example, as shown in FIG. 6, read operations 600 (also referred to as normal read operations) to read data from a TLC memory page can include a read operation 600A to read data from a lower page, a read operation 600B to read data from a middle page, and a read operation 600C to read data from an upper page. Each read operation 600 can include a pre-pulse phase 602 and a sensing phase 604. During the pre-pulse phase 602, a precharge voltage can be applied to the selected word line. During the sensing phase 604, the read voltages can be applied to the selected word line in an ascending order. For example, during the sensing phase 604 of the read operation 600A, the memory device first applies VR1, and then VR5 to the selected word line. During the sensing phase 604 of the read operation 600B, the memory device first applies VR2, then VR4, and then VR6 to the selected word line. During the sensing phase 604 of the read operation 600C, the memory device first applies VR3, and then VR7 to the selected word line.

In some implementations, the memory device applies the read voltages in a descending order, where a higher read voltage is applied before a lower read voltage. For example, when reading a lower page of a TLC memory device, the memory device first applies VR5, and then VR1 to the selected word line. When reading a middle page, the memory device first applies VR6, then VR4, and then VR2 to the selected word line. When reading an upper page, the memory device first applies VR7, and then VR3 to the selected word line.

FIG. 5B illustrates a schematic diagram of an example threshold voltage distribution of memory cells associated with a zero page in a TLC memory device, according to some aspects of the present disclosure. In some implementations, a memory device can program one or more memory pages into zero pages, for example, to close an open word line, close an open block, or in coordination with garbage collection. A zero page does not include valid data, and includes only zeros (also referred to as dummy data).

As shown in FIG. 5B, to program a zero page, memory cells coupled to a selected word line can be programmed to a state 512. Vₜₕ of memory cells in the state 512 is higher than (to the right of) a starting read voltage for reading each of the lower page (starting read voltage being VR1), middle page (starting read voltage being VR2), and upper page (starting read voltage being VR3). For example, Vₜₕ of the state 512 can be the same as Vₜₕ of programmed state L3, or the same as Vₜₕ of programmed state L4, or between Vₜₕ of programmed state L4 and Vₜₕ of programmed state L5. In some implementations, the memory device can program the memory cells to the state 512 using a single program pulse (e.g., in an SLC mode). In some implementations, the memory device can program the memory cells to the state 512 using more than one program pulse, for example, some of the program pulses of an ISPP scheme.

The threshold voltage of state 512 can be pre-determined based on the Gray codes. In some implementations, the threshold voltage of state 512 is higher than the read voltage corresponding to the programmed state where each bit of the three-bit binary code flips for the first time. For example, referring back to FIG. 5A, LSB of the three-bit binary code flips for the first time at L1, CSB of the three-bit binary code flips for the first time at L2, and MSB of the three-bit binary code flips for the first time at L3. As such, the threshold voltage of state 512 can be pre-determined to be higher than the read voltage VR3, which corresponds to L3. It should be noted that the Vₜₕ of state 512 can be pre-determined differently if the eight states are mapped to a different set of Gray codes.

As shown in FIG. 5B, the memory device can determine whether the memory cells are in the state 512 by applying a single read voltage. By applying a starting read voltage of one of the memory pages (that is, VR1 for the lower page, VR2 for the middle page, or VR3 for the upper page) to the selected word line, the majority of the memory cells coupled to the selected word line have Vₜₕ higher than the starting read voltage and are thereby switched off. Only a few memory cells coupled to the selected word line have Vₜₕ lower than the starting read voltage and are thereby switched on (e.g., due to probability density). In comparison, in the Vₜₕ distribution 500 of FIG. 5A, a substantial amount of memory cells (e.g., memory cells in state L0) have Vₜₕ lower than the starting read voltage. As such, the memory device can determine whether the page being read is a zero page by applying the starting read voltage.

For example, the memory device can determine a quantity of the failed memory cells (that is, memory cells having Vₜₕ lower than the read voltage) corresponding to the starting read voltage, and compare the quantity of failed memory cells to a threshold. In some implementations, the memory device can determine the quantity of the failed memory cells (memory cells that are latched as “1”) in the DS latch 412 of the page buffer/sense amplifier 304. The threshold can be set as a value that is lower than ⅛ of the quantity of memory cells coupled to the selected word line in a TLC memory device, for example, 10% or 5% of the quantity of memory cells coupled to the selected word line, or any other suitable value. If the quantity of failed memory cells is less than the threshold, it indicates that the memory page being read is a zero page. In such case, the memory device can end the read operation, and send a response (e.g., returning status E1h) to a memory controller to indicate that the memory page is a zero page. If the quantity of failed memory cells is greater than or equal to the threshold, it indicates that the memory page is not a zero page, and the memory device can proceed with a normal read operation (e.g., as shown in FIG. 6) by applying subsequent read voltages to the selected word line.

In some implementations, during a normal read operation, the memory can apply the read voltages in a descending order, where a higher read voltage is applied before a lower read voltage. Accordingly, as shown in FIG. 5C, to program a zero page, memory cells associated with the zero page can be programmed to a state 522 lower than the highest read voltage for reading each memory page. For example, Vₜₕ of the state 522 can be pre-set to be lower than VR5, which is the starting read voltage to read the lower page in descending order. As such, by applying the starting read voltage (e.g., VR5 for lower page, VR6 for middle page, or VR7 for upper page) of one of the memory pages, the memory device can determine a quantity of passed memory cells having threshold voltages higher than the starting read voltage. If the quantity of passed memory cells is less than a threshold, the memory page being read can be identified as a zero page.

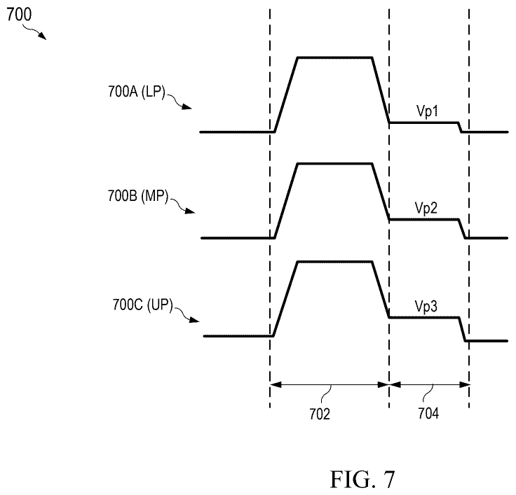

FIG. 7 illustrates an example of voltages applied to a word line during read operations 700 to identify a zero page (also referred to as read zero page operations) in a TLC memory device, according to some aspects of the present disclosure.

Read operations 700 can include a read operation 700A to read a lower page, a read operation 700B to read a middle page, and a read operation 700C to read an upper page. Each read operation 700 can include a pre-pulse phase 702 and a sensing phase 704. During the pre-pulse phase 702, a pre-charge voltage can be applied to the selected word line. During the sensing phase 704, only one read voltage is applied to the selected word line. For example, during the sensing phase 704 of the read operation 700A, the memory device applies VR1 to the word line, determines whether the memory page is a zero page based on VR1, and then ends the read operation 700A. During the sensing phase 704 of the read operation 700B, the memory device applies VR2 to the selected word line, determines whether the memory page is a zero page based on VR2, and then ends the read operation 700B. During the sensing phase 704 of the read operation 700C, the memory device applies VR3 to the selected word line, determines whether the memory page is a zero page based on VR3, and then ends the read operation 700C.

In read operations 700, the memory device can identify zero pages by applying fewer read voltages (e.g., applying a single read voltage) than read operations 600, which can reduce the time needed for read operations 700. In some implementations, the memory device can apply more than one read voltage during the sensing phase 704 of the read operation 700, where the quantity of read voltages is less than the quantity of read voltages applied during the sensing phase 604 of a corresponding normal read operation 600. Further, the memory device can send a response to the memory controller indicating the memory page is a zero page, without sending data read from the zero page to the memory controller, which can reduce the usage of buffer space in the memory controller.

FIG. 8A illustrates an example of threshold voltage distributions of memory cells in a quad-level cell (QLC) memory device, according to some aspects of the present disclosure.

Each memory cell of the QLC memory device (also referred to as quad-level cell or QLC) can be configured to be set as one of 16 states L0-L15, where L0 is the erased state and L1-L15 are programmed states. Each state of the QLC corresponds to a range of threshold voltages Vₜₕ, where the Vₜₕ distribution of each state can be represented by a probability density. As shown in FIG. 8A, from the state L0 to the state L15, Vₜₕ of the memory cell increases. In some implementations, each state of the QLC can be programmed by using an incremental step pulse programming (ISPP) scheme, where the program voltage applied to the selected word line can be incrementally increased by adding a step pulse. For example, the 16 states of QLC can be programmed, from the erase state L0 to the programmed state L1 having a lower threshold voltage, and then to programmed state L2, L3, . . . , L15 having a higher threshold voltage.

The states of a memory cell can be mapped into data in the form of binary codes. For example, the 16 states of a QLC can be represented in the form of a Gray code. As shown in FIG. 8A, each state of the QLC is mapped into a 4-bit binary code. As an example, the 16 states (states L0-L15) of QLC can correspond to 4-bit binary codes (1111), (0111), (0110), (0100), (1100), (1000), (0000), (0010), (0011), (0001), (0101), (1101), (1001), (1011), (1010) and (1110), respectively. Memory cells coupled to the same word line (also referred to as a physical page) can store data in four logic pages, including a lower page (LP), a middle page (MP), an upper page (UP), and an extra page (XP). In some implementations, the states of the memory cell can be mapped to the gray codes in a different order, or can be mapped to a different set of binary codes.

During a read operation, the state of a memory cell can be determined by comparing the threshold voltage (Vₜₕ) of the memory cell with one or more read voltages VR (e.g., VR1, VR2, . . . ). As shown in FIG. 8A, in the QLC memory device, by applying the read voltages VR1-VR15 to the selected word line, the memory device can determine a range of Vₜₕ of a target memory cell coupled to the selected word line. By measuring or sensing the current through the target memory cell or sensing a voltage drop at the corresponding bit line, the memory device can determine Vₜₕ or the state of the target memory cell.

In some implementations, the states of the memory cells are read and determined according to the logic pages of the mapping scheme. For example, in a normal read operation (a read operation to read data from the memory pages) of a QLC memory device, a first subset of the read voltages, e.g., VR1, VR4, VR6, and VR11, can be used to determine the most significant bit of the target memory cell (corresponding to the extra page) where “1” is flipped to “0” or “0” is flipped to “1”. Similarly, a second subset of the read voltages, e.g., VR5, VR10, VR12, and VR15, can be used to determine the second most significant bit of the target memory cell (corresponding to the upper page), a third subset of the read voltages, e.g., VR3, VR7, VR9, and VR13, can be used to determine the third most significant bit of the target memory cell (corresponding to the middle page), and a fourth subset of read voltages, e.g., VR2, VR8 and VR14, can be used to determine the least significant bit of the target memory cell (corresponding to the lower page). Accordingly, the data can be read from the extra page (XP) by applying four read voltages to the selected word line. Data can be read from the upper page (UP) by applying four read voltages to the selected word line. Data can be read from the middle page (MP) by applying four read voltages to the selected word line. Data can be read from the lower page (LP) by applying three read voltages to the selected word line.

FIG. 8B illustrates a schematic diagram of an example threshold voltage distribution of memory cells associated with a zero page in a QLC memory device, according to some aspects of the present disclosure.

As shown in FIG. 8B, to program a zero page, memory cells coupled to a selected word line can be programmed to a state 812. Vₜₕ of memory cells in the state 812 is higher than (to the right of) a starting read voltage for reading each of the lower page (starting read voltage being VR2), the middle page (starting read voltage being VR3), the upper page (starting read voltage being VR5) and the extra page (starting read voltage being VR1). For example, Vₜₕ of the state 812 can be the same as Vₜₕ of programmed state L6, or the same as Vₜₕ of programmed state L7, or between Vₜₕ of programmed state L7 and Vₜₕ of programmed state L8. In some implementations, the memory device can program the memory cells to the state 812 using a single program pulse (e.g., in an SLC mode). In some implementations, the memory device can program the memory cells to the state 812 using more than one program pulse, for example, some of the program pulses of an ISPP scheme.

The threshold voltage of state 812 can be pre-determined based on the Gray codes. In some implementations, the threshold voltage of state 812 is higher than the read voltage corresponding to the programmed state where each bit of the 4-bit binary code flips for the first time. For example, referring back to FIG. 8A, the least significant bit of the 4-bit binary code flips for the first time at L2, the third most significant bit of the 4-bit binary code flips for the first time at L3, the second most significant bit of the 4-bit binary code flips for the first time at L5, and the most significant bit of the 4-bit binary code flips for the first time at L1. As such, the threshold voltage of state 812 can be pre-determined to be higher than the read voltage VR5, which corresponds to L5. It should be noted that the Vₜₕ of state 812 can be pre-determined differently if the 16 states are mapped to a different set of Gray codes.

As shown in FIG. 8B, the memory device can determine whether the memory cells are in state 812 by applying a single read voltage, or by applying fewer read voltages than the read voltages needed for a normal read operation.

In some implementations, by applying a starting read voltage of one of the memory pages (that is, VR2 for the lower page, VR3 for the middle page, VR5 for the upper page, or VR1 for the upper page) to the selected word line, the majority of the memory cells coupled to the selected word line have Vₜₕ higher than the starting read voltage and are thereby switched off. Only a few memory cells coupled to the selected word line have Vₜₕ lower than the starting read voltage and are thereby switched. In comparison, in the Vₜₕ distribution 800 of FIG. 8A, a substantial amount of memory cells (e.g., memory cells in state P0) have Vₜₕ lower than the starting read voltage. As such, the memory device can determine whether the page being read is a zero page by applying the starting read voltage.

For example, the memory device can determine a quantity of the failed memory cells (that is, memory cells having Vₜₕ lower than the read voltage) corresponding to the starting read voltage, and compare the quantity of failed memory cells to a threshold. The threshold can be set as a value that is lower than 1/16 of the quantity of memory cells coupled to the selected word line in a QLC memory device, for example, 5% or 3% of the quantity of memory cells coupled to the selected word line, or any other suitable value. If the quantity of failed memory cells is less than the threshold, it indicates that memory page being read is a zero page. In such case, the memory device can end the read operation, and send a response (e.g., returning status E1h) to a memory controller to indicate that the memory page is a zero page. If the quantity of failed memory cells is greater than or equal to the threshold, it indicates that the memory page is not a zero page, and the memory device can proceed with a normal read operation by applying subsequent read voltages to the selected word line.

In some implementations, the memory device can be an xLC memory device, where x equals 3, 4, 5, or higher. The xLC memory device can program and identify zero pages by implementing a similar technical scheme as discussed with reference to FIG. 5B, FIG. 5C, FIG. 7 and FIG. 8B.

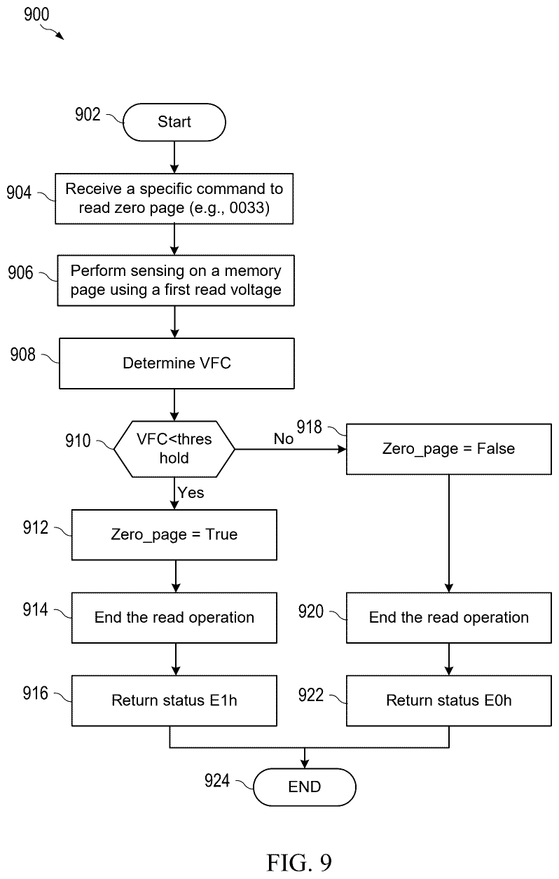

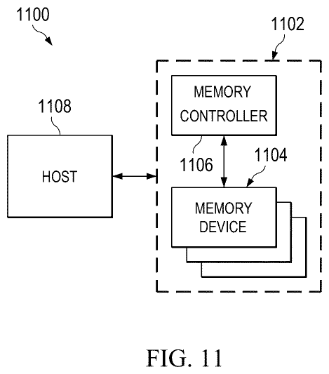

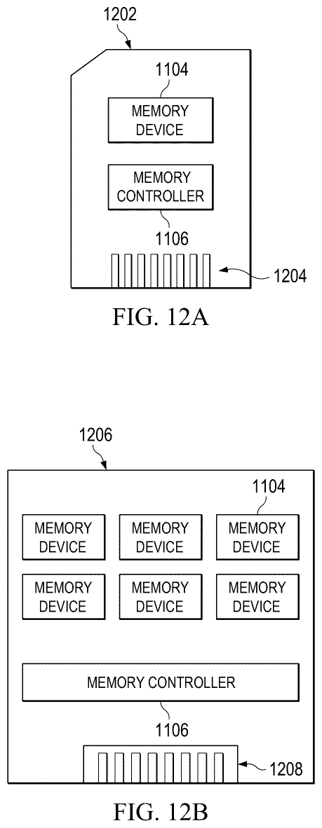

FIG. 9 illustrates a flow chart of an example process 900 of performing a read operation (e.g., a read operation 700) to identify a zero page, according to some aspects of the present disclosure. The process 900 can be performed by any suitable device or system as described herein, for example, according to the example techniques described with respect to FIGS. 1-8. For example, the process 900 can be performed by a memory device, such as the memory device 100 of FIGS. 1 and 3, or the memory device 1104 of FIG. 11-12B.

In the process 900, the memory device can perform the read operation in response to receiving a specific command (e.g., with operation code 0033) that indicates to identify zero pages. The process 900 starts at 902.

At 904, the memory device receives the specific command from a memory controller (e.g., the memory controller 1106 of FIGS. 11-12B). The specific command indicates to perform a read operation on memory cells coupled to a selected word line (e.g., word line 118 of FIG. 1), where the read operation is configured to determine whether a memory page associated with the selected word line is a zero page.

At 906, the memory device performs sensing on the memory page by applying a first read voltage to the selected word line. The first read voltage can be a starting read voltage for a normal read operation (e.g., read operation 600) configured to read data from the memory page. For example, the first read voltage can be VR1 for a lower page of a TLC, VR2 for a middle page of a TLC, or VR3 for an upper page of a TLC. For another example, the first read voltage can be VR2 for a lower page of a QLC, VR3 for a middle page of a QLC, VR5 for an upper page of a QLC, or VR1 for an extra page of a QLC.

At 908, the memory device determines a result of verify fail count (VFC) corresponding to the first read voltage. The result of the VFC includes a quantity of failed memory cells having threshold voltages lower than the first read voltage. In some implementations, a failed memory cell is read as logic value “1” and latched to a latch (e.g., DS latch 412 of FIG. 4) of a page buffer (e.g., page buffer 304 of FIGS. 3-4). The memory device can determine the quantity of the failed memory cells by determining the sum of logic value “1”in the latch.

At 910, the memory device determines whether the result of VFC (e.g. quantity of failed memory cells) is less than a threshold. In some implementations, the threshold can be a value that is less than 5% of a quantity of memory cells coupled to the selected word line. In response to determining that the result of VFC is less than the threshold, the process 900 proceeds to 912.

At 912, the memory device determines that the memory page being read is a zero page. As discussed with reference to FIG. 5B and FIG. 8B, when a memory page is programmed into a zero page, memory cells coupled to the word line associated with the zero page have threshold voltages higher than a threshold level. The threshold level (e.g., VR3 for TLC, or VR5 for QLC) is higher than a starting read voltage for reading each of the memory pages (e.g., lower page, middle page, and upper page for TLC, or lower page, middle page, upper page, and extra page for QLC) associated with the word line.

At 914, the memory device ends the read operation. The memory device does not apply subsequent read voltages to the selected word line, as opposed to a normal read operation (e.g., read operation 600 of FIG. 6).

At 916, the memory device sends a response (e.g., status E1h) to the memory controller. The response indicates that the memory page being read is a zero page.

In response to determining that the result of VFC is greater than or equal to the threshold at 910, the process 900 proceeds to 918.

At 918, the memory device determines that the memory page being read is not a zero page.

At 920, the memory device ends the read operation.

At 922, the memory device sends a response (e.g., status E0h) to the memory controller. The response indicates that the memory page being read is not a zero page, and that the read operation to identify zero pages has ended.

The process 900 ends at 924.

The operations shown in process 900 may not be exhaustive and other operations can be performed as well before, after, or in between any of the illustrated operations. Further, some of the operations may be performed simultaneously, or in a different order than shown in FIG. 9. In some implementations, some of the operations may be performed by one or more components of a device or a system, such as, a peripheral circuit of the memory device, or a memory controller of a memory system.

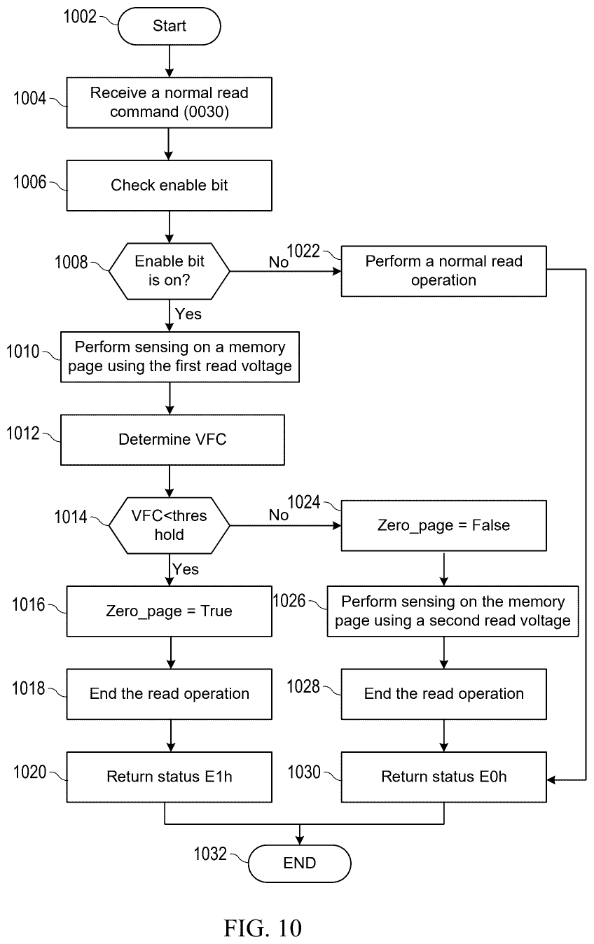

FIG. 10 illustrates a flow chart of another example process 1000 of performing a read operation (e.g., a read operation 700) to identify a zero page, according to some aspects of the present disclosure. The process 1000 can be performed by any suitable device or system as described herein, for example, according to the example techniques described with respect to FIGS. 1-8. For example, process 1000 can be performed by a memory device, such as the memory device 100 of FIGS. 1 and 3, and the memory device 1104 of FIG. 11-12B.

In the process 1000, the memory device can perform the read operation in response to receiving a normal read command (e.g., with operation code 0030) and checking whether an enable bit is switched on. If the enable bit is switched on (e.g., being “1”), the memory device can identify zero pages during the read operation. If the enable bit is switched off (e.g., being “0”), the memory device will perform a normal read operation to read data from the memory page. The process 1000 starts at 1002.

At 1004, the memory device receives a normal read command from a memory controller (e.g., the memory controller 1106 of FIGS. 11-12B). The normal read command indicates to perform a read operation on memory cells coupled to a selected word line (e.g., word line 118 of FIG. 1).

At 1006, the memory device checks the enable bit. The enable bit can be stored in a register of the memory device. In some implementations, the memory controller can send configuration information (e.g., a set feature) to the memory device to switch the enable bit from 0 to 1, or 1 to 0.

At 1008, in response to determining the enable bit is switched on, which indicates to identify zero pages during the read operation, the process 1000 proceeds to 1010. In response to determining the enable bit is switched off, which indicates to perform a normal read operation, the process 1000 proceeds to 1022. At 1022, the memory device performs a normal read operation (e.g., a read operation 600 of FIG. 6).

At 1010, similar to 906 of process 900, the memory device performs sensing on the memory page by applying a first read voltage to the selected word line. The first read voltage can be a starting read voltage of a normal read operation (e.g., read operation 600). For example, the first read voltage can be VR1 for a lower page of a TLC, VR2 for a middle page of a TLC, or VR3 for an upper page of a TLC. For another example, the first read voltage can be VR2 for a lower page of a QLC, VR3 for a middle page of a QLC, VR5 for an upper page of a QLC, or VR1 for an extra page of a QLC.

At 1012, similar to 908 of process 900, the memory device determines a result of verify fail count (VFC) corresponding to the first read voltage. The result of the VFC includes a quantity of failed memory cells having threshold voltages lower than the first read voltage. In some implementations, a failed memory cell is read as logic value “1” and latched to a latch (e.g., DS latch 412 of FIG. 4) of a page buffer (e.g., page buffer 304 of FIGS. 3-4). The memory device can determine the quantity of the failed memory cells by determining the sum of logic value “1” in the latch.

At 1014, similar to 910 of process 900, the memory device determines whether the result of VFC (e.g. quantity of failed memory cells) is less than a threshold. In some implementations, the threshold can be a value that is less than 5% of a quantity of memory cells coupled to the selected word line. In response to determining that the result of VFC is less than the threshold, the process 1000 proceeds to 1016.

At 1016, similar to 912 of process 900, the memory device determines that the memory page being read is a zero page.

At 1018, similar to 914 of process 900, the memory device ends the read operation. The memory device does not apply subsequent read voltages to the selected word line, as opposed to a normal read operation (e.g., read operation 600 of FIG. 6).

At 1020, similar to 916 of process 900, the memory device sends a response (e.g., status E1h) to the memory controller. The response indicates that the memory page being read is a zero page.

In response to determining that the result of VFC is greater than or equal to the threshold at 1014, the process 1000 proceeds to 1024.

At 1024, the memory device determines that the memory page being read is not a zero page.

At 1026, the memory device continues to perform a normal read operation on the memory page. The memory device can perform sensing on the memory page by applying a second read voltage that is higher than the first read voltage. For example, the second read voltage can be VR5 when reading a TLC lower page, VR2 and VR6 when reading a TLC middle page, or VR7 when reading a TLC upper page. For another example, the second read voltage can be VR8 and VR14 for a QLC lower page, VR7, VR9 and VR13 for a QLC middle page, VR10, VR12 and VR15 for a QLC upper page, or VR4, VR6 and VR11 for a QLC extra page.

At 1028, the memory device ends the normal read operation. Further, the memory device can send data read from the memory page to the memory controller.

At 1030, the memory device sends a response (e.g., status E0h) to the memory controller. The response indicates that the read operation has ended, and that the memory page being read is not a zero page.

The process 1000 ends at 1032.

The operations shown in process 1000 may not be exhaustive and other operations can be performed as well before, after, or in between any of the illustrated operations. Further, some of the operations may be performed simultaneously, or in a different order than shown in FIG. 10. In some implementations, some of the operations may be performed by one or more components of a device or a system, such as, a peripheral circuit of the memory device, or a memory controller of a memory system.

FIG. 11 illustrates a block diagram of an example system 1100 having a memory device, according to some aspects of the present disclosure. System 1100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 11, system 1100 can include a host 1108 and a memory system 1102 having one or more memory devices 1104 and a memory controller 1106. Host 1108 can be a processor of an electronic device, such as a central processing unit (CPU), or a system-on-chip (SoC), such as an application processor (AP). Host 1108 can be configured to send or receive data to or from memory devices 1104.

Memory device 1104 can be any memory device disclosed in the present disclosure. Memory controller 1106 is coupled to memory device 1104 and host 1108 and is configured to control memory device 1104, according to some implementations. Memory controller 1106 can manage the data stored in memory device 1104 and communicate with host 1108. In some implementations, memory controller 1106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1106 can be configured to control operations of memory device 1104, such as read, erase, and program operations. Memory controller 1106 can also be configured to manage various functions with respect to the data stored or to be stored in memory device 1104 including, but not limited to bad-block management, garbage collection, logical-to-physical address conversion, wear leveling, etc. In some implementations, memory controller 1106 is further configured to process error correction codes (ECCs) with respect to the data read from or written to memory device 1104. Any other suitable functions may be performed by memory controller 1106 as well, for example, formatting memory device 1104.

Memory controller 1106 can communicate with an external device (e.g., host 1108) according to a particular communication protocol. For example, memory controller 1106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1106 and one or more memory devices 1104 can be integrated into various types of storage devices, for example, be included in the same package, such as a universal Flash storage (UFS) package or an eMMC package. That is, memory system 1102 can be implemented and packaged into different types of end electronic products. In one example as shown in FIG. 12A, memory controller 1106 and a memory device 1104 may be integrated into a memory card 1202. Memory card 1202 can include a PC card (PCMCIA, personal computer memory card international association), a CF card, a smart media (SM) card, a memory stick, a multimedia card (MMC, RS-MMC, MMCmicro) , an SD card (SD, miniSD, microSD, SDHC), a UFS, etc. Memory card 1202 can further include a memory card connector 1204 coupling memory card 1202 with a host (e.g., host 1108 in FIG. 11). In another example as shown in FIG. 12B, memory controller 1106 and multiple memory devices 1104 may be integrated into an SSD 1206. SSD 1206 can further include an SSD connector 1208 coupling SSD 1206 with a host (e.g., host 1108 in FIG. 11). In some implementations, the storage capacity and/or the operation speed of SSD 1206 is greater than those of memory card 1202.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

It is noted that references in the specification to “one implementation,” “an implementation,” “an example implementation,” “some implementation,” etc., indicate that the implementation described can include a particular feature, structure, or characteristic, but every implementation may not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to affect such feature, structure, or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures, or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and can, instead, allow for existence of additional factors not necessarily expressly described, again, depending at least in part on context.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, there above, and/or there below. A layer can include multiple layers. For example, an interconnect layer can include one or more conductive and contact layers (in which contacts, interconnect lines, and/or vertical interconnect accesses (VIAs) are formed) and one or more dielectric layers.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,”unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A method of operating a memory device, comprising:
performing, based on a first read voltage, a read operation on memory cells coupled to a word line of the memory device;
determining a quantity of failed memory cells, wherein the failed memory cells are memory cells having threshold voltages lower than the first read voltage; and
in response to determining that the quantity of the failed memory cells is less than a threshold, ending the read operation.

2. The method of claim 1, wherein the threshold is a value that is less than 5% of a quantity of memory cells coupled to the word line.

3. The method of claim 1, wherein determining the quantity of the failed memory cells comprises:
determining, in latches of a page buffer of the memory device, a quantity of memory cells that are read as “1”.

4. The method of claim 1, comprising:
in response to determining that the quantity of the failed memory cells is less than the threshold, sending a response indicating that a memory page associated with the word line is a zero page.

5. The method of claim 4, wherein the zero page is associated with a word line coupled to a set of memory cells, wherein threshold voltages of the set of memory cells are higher than a threshold level that is higher than a starting read voltage for reading each of a plurality of memory pages of the memory device.

6. The method of claim 1, wherein the memory cells are triple-level cells, and wherein the first read voltage is a starting read voltage for reading one of a lower page, a middle page, or an upper page associated with the word line.

7. The method of claim 1, wherein the memory cells are quad-level cells, and wherein the first read voltage is a starting read voltage for reading one of a lower page, a middle page, an upper page, or an extra page associated with the word line.

8. The method of claim 1, comprising:
performing the read operation in response to receiving a specific command indicating to identify zero pages in the memory device.

9. The method of claim 1, comprising:
performing the read operation in response to:
receiving a read command; and
determining that an enable bit stored in the memory device indicates the memory device to identify zero pages when performing the read operation.

10. The method of claim 9, further comprising:
in response to determining that the quantity of failed memory cells is greater than or equal to the threshold, performing the read operation based on a second read voltage on the memory cells, wherein the second read voltage is higher than the first read voltage.

11. A memory device, comprising:
a memory array comprising memory cells coupled to a word line; and
a peripheral circuit coupled to the memory array, wherein the peripheral circuit is configured to perform operations comprising:
performing, based on a first read voltage, a read operation on memory cells coupled to a word line of the memory device;
determining a quantity of failed memory cells, wherein threshold voltages of the failed memory cells are lower than the first read voltage; and
in response to determining that the quantity of failed memory cells is less than a threshold, ending the read operation.

12. The memory device of claim 11, wherein the threshold is a value that is less than 5% of a quantity of memory cells coupled to the word line.

13. The memory device of claim 11, wherein determining the quantity of the failed memory cells comprises:
determining, in latches of a page buffer of the memory device, a quantity of memory cells that are read as “1”.

14. The memory device of claim 11, wherein the operations comprise:
in response to determining that the quantity of the failed memory cells is less than the threshold, sending a response indicating that a memory page associated with the word line is a zero page.

15. The memory device of claim 14, wherein the zero page is associated with a word line coupled to a set of memory cells, wherein threshold voltages of the set of memory cells are higher than a threshold level that is higher than a starting read voltage for reading each of a plurality of memory pages of the memory device.

16. The memory device of claim 11, wherein the memory cells are triple-level cells, and wherein the first read voltage is a starting read voltage for reading one of a lower page, a middle page, or an upper page associated with the word line.

17. The memory device of claim 11, wherein the memory cells are quad-level cells, and wherein the first read voltage is a starting read voltage for reading one of a lower page, a middle page, an upper page, or an extra page associated with the word line.

18. A memory system, comprising:
a memory device comprising memory cells coupled to a word line; and
a memory controller coupled to the memory device, wherein the memory device is configured to perform operations comprising:
receiving a read command from the memory controller;
performing, based on a first read voltage, a read operation on the memory cells;
determining a quantity of failed memory cells, wherein the failed memory cells are memory cells having threshold voltages lower than the first read voltage; and
in response to a result of the read operation, sending a response to the memory controller, wherein the response indicates that a memory page associated with the word line is a zero page.

19. The memory system of claim 18, wherein the operations comprise:
determining a quantity of failed memory cells, wherein the failed memory cells are memory cells having threshold voltages lower than the first read voltage,
wherein the memory device is configured to send the response to the memory controller in response to determining that the quantity of the failed memory cells is less than a threshold.

20. The memory system of claim 19, wherein the operations comprise:
in response to determining that the quantity of the failed memory cells is less than the threshold, ending the read operation.
